(19) United States
(12) Patent Application Publication
(10) Pub. No.: US 2009/0050308 A1
(43) Pub. Date: Feb. 26, 2009

(54) Base Structure for a Heat Sink

(76) Inventor: Yung-Pin KUO, Changhua City (TW)

Correspondence Address: Dr. BANGER SHIA, 102 Lindencrest Ct., Sugar Land, TX, 77479-5201, US

(21) Appl. No.: 11/841,663

(22) Filed: Aug. 20, 2007

(51) Int. Cl. H01L 23/34

(52) U.S. Cl. 165/185

(57) ABSTRACT

A base structure for a heat sink comprises: a heat conducting plate, a positioning piece, a plurality of legs and fasteners. The heat conducting plate is assembled together with the heat conducting plate to form two opposite guiding channels. The legs are positioned in the guiding channel by the fasteners. The fasteners are movable along the guiding channel along with the legs, and the legs are rotatable around the corresponding fastener, so that the positions of the legs are adjustable. Furthermore, the guiding channels is formed by the concave portion of the heat conducting plate and the groove of the positioning piece, and the heat conducting plate and the positioning piece can be produced separately, thus making it easier to produce the guiding channel.

### BACKGROUND OF THE INVENTION

1. Field of the Invention

The present invention relates to a cooling device for an electronic component, and more particularly to a base structure for a heat sink.

2. Description of the Prior Art

Conventional heat sinks used on the computer host have various types and configurations, but basically comprise a plurality of heat pipes with both ends connected to a plurality of fins, and a base. Heat sink bases are also various in forms and structures. One of the base structures, as shown in FIG. 1, comprises a heat conducting plate 10, a clamping block 20 and two positioning pieces 30. The heat conducting plate 10 and the clamping block 20 are fixed together by screws to sandwich a plurality of heat pipes A and the two positioning pieces 30 therebetween. Each positioning piece 30 includes two legs 31 for positioning the base.

The heat sink base structure of such type has the following disadvantages. If the assembly position is inconsistent with the legs 31, the base of the heat sink cannot be installed since the legs 31 are unadjustable in angle and position.

Another base structure for a heat sink is shown in FIG. 2 and comprises a heat conducting plate 10, a clamping block 20 and a plurality of legs 40. The heat conducting plate 10 and the clamping block 20 are fixed together to sandwich a plurality of heat pipes A and the two positioning pieces 30 therebetween. A linear sliding groove 11 is formed at each side of the heat conducting plate 10 and includes two open ends and one open side. Each sliding groove 11 is formed with two stop flanges 12 at opposite edges of the open side thereof. In each of the sliding grooves 11 is restricted a nut B which is stopped by the stop flanges 12 and can only be taken out via the two open ends of the slide grooves 11. Each of the legs 40 is defined at one end thereof with a through hole 41 through which a screw C is screwed with the nut B for enabling the legs 40 and the nuts B to clamp against the stop flanges 12, such that the legs 40 is positioned on the heat conducting plate 10. Theses legs 40 are provided for positioning the base and are rotatable around the screws C. And the screws C can slide within the slide grooves 11 to adjust the positions of the legs 40.

Such type of heat sink base is difficult to manufacture, since forming the sliding grooves 11 with the stop flanges 12 in the heat conducting plate 10 requires the processes of cutting, grinding, machining, milling, punching, pressing, and etc, and each process has some difficulties and complexities. The manufacturing difficulties always lead to the increase of cost.

The present invention has arisen to mitigate and/or obviate the afore-described disadvantages.

### SUMMARY OF THE INVENTION

The primary objective of the present invention is to provide a low cost and easily produced base structure for a heat sink the legs of which can be adjusted to meet the different assembly requirements.

To achieve the above objective, the base structure comprises: a heat conducting plate, a positioning piece, a plurality of legs and fasteners. The heat conducting plate is assembled together with the heat conducting plate to clamp the heat pipes between them. At each of two opposite side walls of the heat conducting plate are formed a convex portion and a concave portion, respectively, the convex portion and the concave portion of the same side being adjacent to each other. At each of two opposite side walls of the positioning piece are formed a flange and a groove for engaging with the convex portion and the concave portion of the heat conducting plate, respectively, the convex portion of the heat conducting plate and the flange at a corresponding side of the positioning piece are opposite each other, and the concave portion of the heat conducting plate and the groove at a corresponding side of the positioning piece are opposite each other to define a guiding channel. The legs are positioned in the guiding channel by the fasteners.

The fasteners are movable along the guiding channel along with the legs, and the legs are rotatable around the corresponding fastener, so that the positions of the legs are adjustable. Furthermore, the guiding channels is formed by the concave portion of the heat conducting plate and the groove of the positioning piece, and the heat conducting plate and the positioning piece can be produced separately, thus making it easier to produce the guiding channel.

### BRIEF DESCRIPTION OF THE DRAWINGS

FIG. 1 is a perspective view of a conventional base structure for a heat sink;

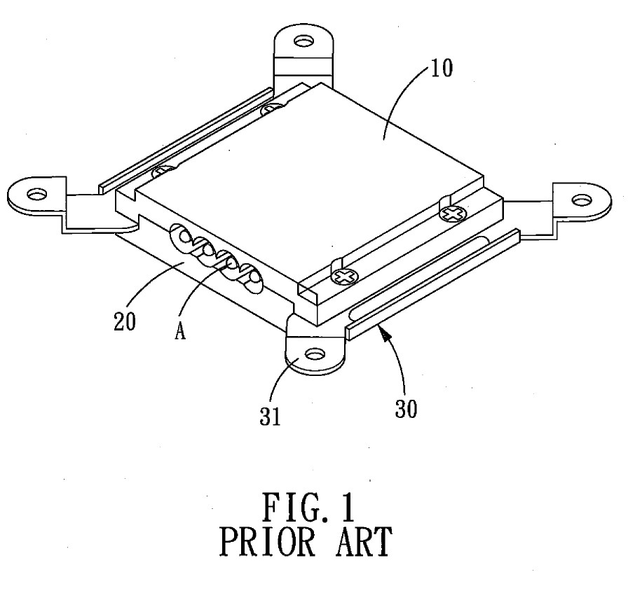

FIG. 2 is a perspective view of another conventional base structure for a heat sink;

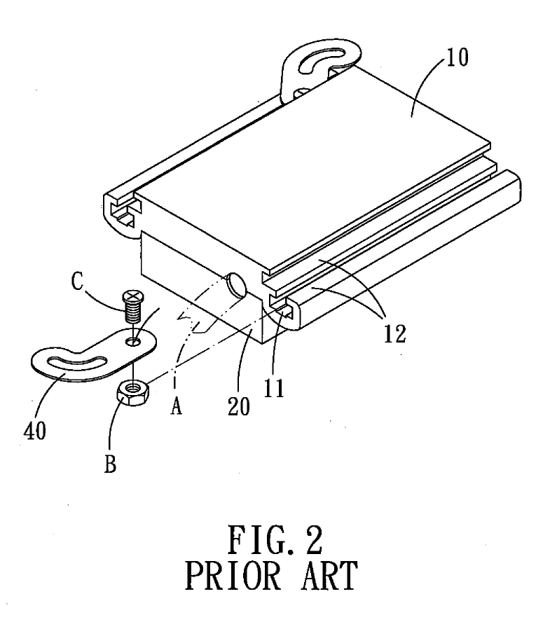

FIG. 3 is an exploded view of a base structure for a heat sink in accordance with the present invention;

FIG. 4 is an assembly view of the base structure for a heat sink in accordance with the present invention;

FIG. 5 is a cross sectional view of showing the operation of positioning the legs of the base structure in accordance with the present invention;

FIG. 6 is a cross sectional view of showing a second embodiment of the guiding channel in accordance with the present invention;

FIG. 7 is a cross sectional view of showing a third embodiment of the guiding channel in accordance with the present invention; and

FIG. 8 is a cross sectional view of showing a fourth embodiment of the guiding channel in accordance with the present invention.

### DETAILED DESCRIPTION OF THE PREFERRED EMBODIMENTS

The present invention will be clearer from the following description when viewed together with the accompanying drawings, which show, for purpose of illustrations only, the preferred embodiment in accordance with the present invention.

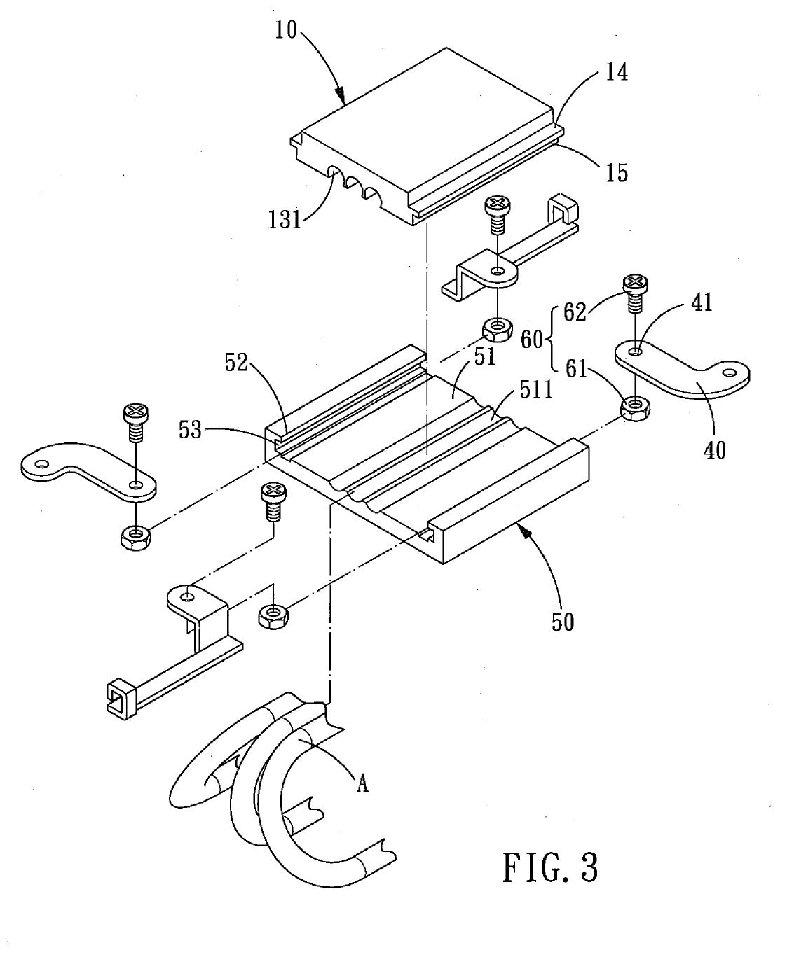

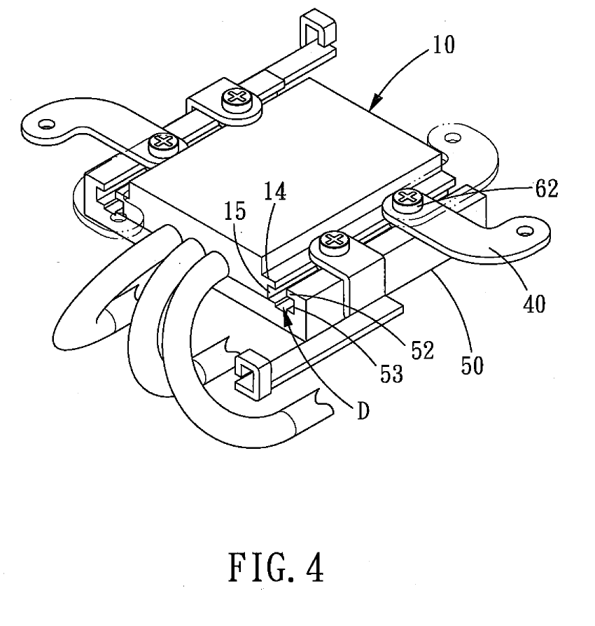

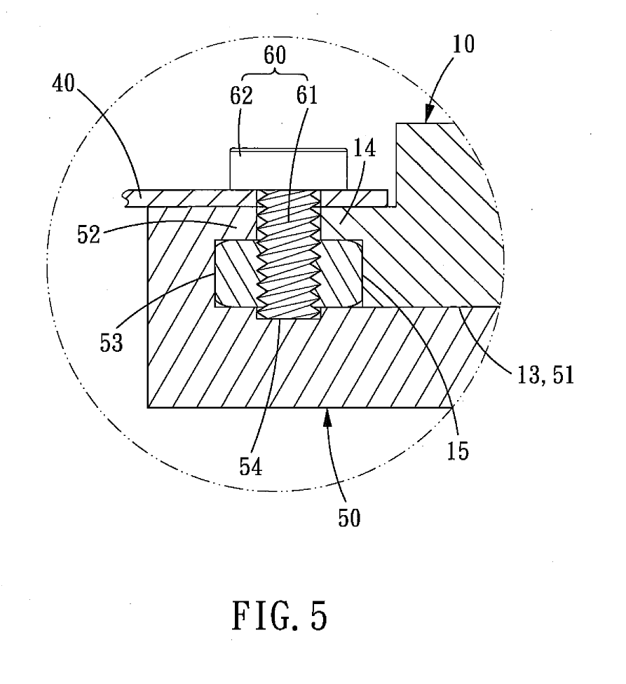

Referring to FIGS. 3-5, a base structure for a heat sink in accordance with the present invention comprises: a heat conducting plate 10, a positioning piece 50, and four legs 40.

The heat conducting plate 10 includes a contacting surface 13 in which is formed a plurality of grooves 131 for accommodation of heat pipe A. At each of two opposite side walls of the heat conducting plate 10 are formed a convex portion 14 and a concave portion 15, respectively. These convex portions 14 and concave portions 15 are located at both sides of the contacting surface 13. And the convex portion 14 and the concave portion 15 of the same side are adjacent to each other.

The positioning piece 50 has a positioning surface 51 in which is formed a plurality of concave portions 511. The contacting surface 13 of the heat conducting plate 10 cooperates with the positioning surface 51 of the positioning piece 50 to position the heat pipes A in such a manner that the heat pipes A are clamped between the grooves 131 of the heat conducting plate 10 and the concave portions 511 of the positioning piece 50. At each of two opposite side walls of the positioning piece 50 are formed a flange 52 and a groove 53 for engaging with the convex portion 14 and the concave portion 15 of the heat conducting plate 10, respectively. The convex portion 14 of the heat conducting plate 10 and the flange 52 at the corresponding side of the positioning piece 50 are opposite each other, and the concave portion 15 of the heat conducting plate 10 and the groove 53 at the corresponding side of the positioning piece 50 are opposite each other to define a guiding channel D. In this embodiment, the convex portion 14 is located in the middle of the side wall of the heat conducting plate 10. And a depressed portion 54 is defined in the positioning surface 51 of the positioning piece 50.

Each leg 40 has a through hole 41 defined at one end thereof. Four fasteners 60 pass through the through holes 41 to position the legs 40 into the guiding channel D. In this embodiment, each fastener 60 includes a nut 61 and a screw 62. The nuts 61 are received in the guiding channel D. The screws 62 are screwed through the through holes 41 of the legs 40 into the nuts 61. The screws 62 cooperate with the convex portions 14 of the heat conducting plate 10 and the flanges 52 of the positioning piece 50 to clamp the legs 40, and the screws 62 are pressed into the depressed portion 54 of the positioning piece 50.

It is understood from the above description that each of the guiding channels D is formed by the concave portion 15 of the heat conducting plate 10 and the groove 53 of the positioning piece 50. And the heat conducting plate 10 and the positioning piece 50 can be produced separately, thus making it easier to produce the guiding channel D.

In addition, each legs 40 is rotatable around the screw 62 of the fastener 60, and the nuts 61 are slidable along the guiding channels D, so that the position and the angle of the legs 40 can be adjusted to meet the different assembly requirements.

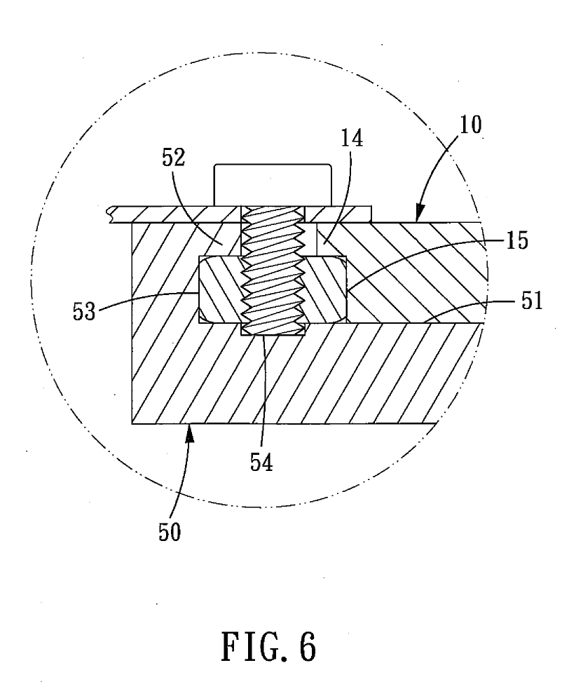

Furthermore, the base of the heat sink can also be as shown in FIG. 6, the convex portion 14 and the concave portion 15 are located at the top and bottom of the side walls of the heat conducting plate 10, respectively. A depressed portion 54, and the screws 62 are pressed into the depressed portion 54 of the positioning piece 50.

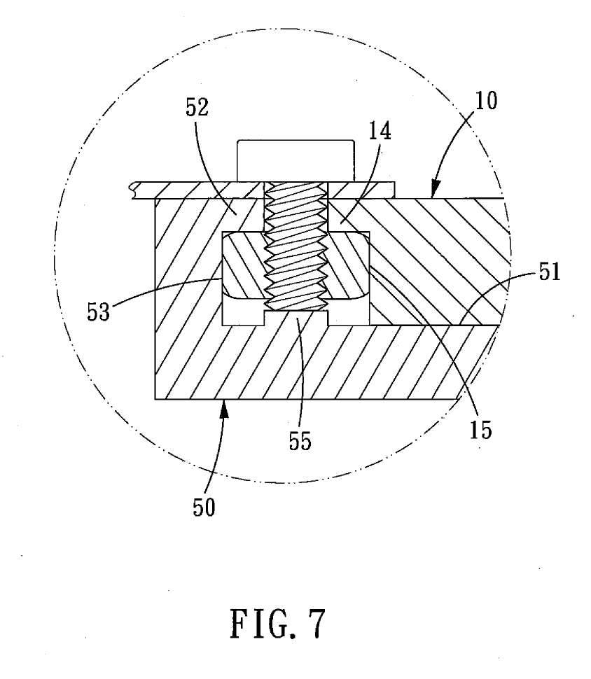

It can also be as shown in FIG. 7, the convex portion 14 and the concave portion 15 are located at the top and bottom of the side walls of the heat conducting plate 10, respectively. A convex portion 55 is formed on the positioning surface 51 of the positioning piece 50, and the screws 62 are pressed onto the convex portion 55 of the positioning piece 50.

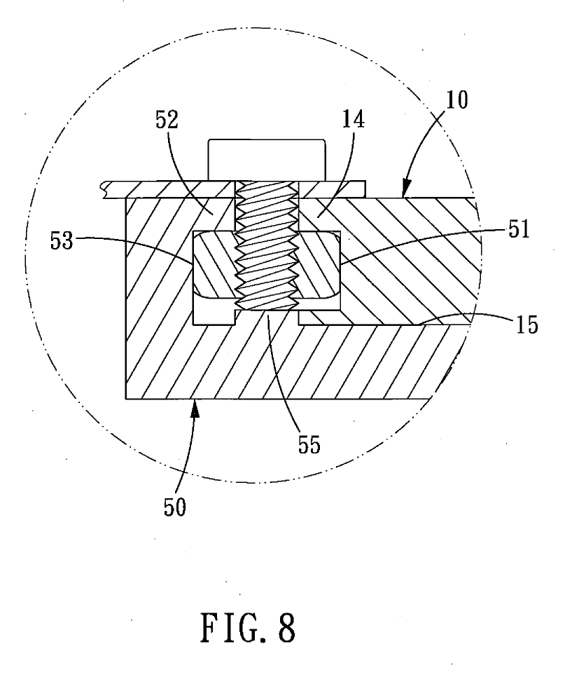

It can also be as shown in FIG. 8, the concave portion 15 is located in the middle of the side wall of the heat conducting plate 10. A convex portion 55 is formed on the positioning surface 51 of the positioning piece 50, and the screws 62 are pressed onto the convex portion 55 of the positioning piece 50.

While we have shown and described various embodiments in accordance with the present invention, it is clear to those skilled in the art that further embodiments may be made without departing from the scope of the present invention.

What is claimed is:

1. A base structure for a heat sink being connected to heat pipes, comprising:
a heat conducting plate, at each of two opposite side walls of which being formed a convex portion and a concave portion, respectively, the convex portion and the concave portion of the same side being adjacent to each other;
a positioning piece assembled together with the heat conducting plate to clamp the heat pipes between them, at each of two opposite side walls of the positioning piece being formed a flange and a groove for engaging with the convex portion and the concave portion of the heat conducting plate, respectively, the convex portion of the heat conducting plate and the flange at a corresponding side of the positioning piece are opposite each other, and the concave portion of the heat conducting plate and the groove at a corresponding side of the positioning piece are opposite each other to define a guiding channel;
a plurality of legs each having a through hole defined at one end thereof, a plurality of fasteners being passed through the through holes of the legs to position the legs into the guiding channel, the fasteners being movable along the guiding channel along with the legs, and the legs being rotatable around the corresponding fastener.

2. The base structure for a heat sink as claimed in claim 1, wherein the heat conducting piece has a contacting surface in which is formed a plurality of grooves, the convex portions and concave portions are located at both sides of the contacting surface, the positioning piece has a positioning surface in which is formed a plurality of concave portions for clamping the heat pipe by cooperating with the grooves of the contacting surface.

3. The base structure for a heat sink as claimed in claim 1, wherein each fastener includes a nut and a screw, the nuts are received in the guiding channel, the screw are screwed through the through holes of the respective legs into the nuts, the screws cooperates with the convex portions of the heat conducting plate and the flanges of the positioning piece to clamp the legs.

4. The base structure for a heat sink as claimed in claim 1, wherein the positioning piece has a positioning surface and is assembled together with the heat conducting plate, a depressed portion is defined in the positioning surface of the positioning piece, the fasteners are pressed into the depressed portion, the convex portion is located in a middle of each of two opposite side walls of the heat conducting plate.

5. The base structure for a heat sink as claimed in claim 1, wherein the positioning piece has a positioning surface and is assembled together with the heat conducting plate, a depressed portion is defined in the positioning surface of the positioning piece, the fasteners are pressed into the depressed portion, the convex portion and the concave portion are located at the top and bottom of the side walls of the heat conducting plate, respectively.

6. The base structure for a heat sink as claimed in claim 1, wherein the positioning piece has a positioning surface and is assembled together with the heat conducting plate, a convex portion is defined on the positioning surface of the positioning piece, the fasteners are pressed onto the depressed portion, the convex portion and the concave portion are located at the top and bottom of the side walls of the heat conducting plate, respectively.

7. The base structure for a heat sink as claimed in claim 1, wherein the positioning piece has a positioning surface and is assembled together with the heat conducting plate, a convex portion is defined on the positioning surface of the positioning piece, the fasteners are pressed onto the depressed portion, the convex portion is located in a middle of each of two opposite side walls of the heat conducting plate.
